(19) United States
(12) Patent Application Publication
(10) Pub. No.: US 2017/0358565 A1
(43) Pub. Date: Dec. 14, 2017

(54) STANDARD CELL LAYOUT AND METHOD OF ARRANGING A PLURALITY OF STANDARD CELLS

(71) Applicant: GLOBALFOUNDRIES Inc., Grand Cayman (KY)

(72) Inventors: Ulrich Hensel, Radeberg (DE); Michael Zier, Dresden (DE); Navneet Jain, Milpitas, CA (US); Rainer Mann, Dresden (DE)

(21) Appl. No.: 15/177,417

(22) Filed: Jun. 9, 2016

(51) Int. Cl. H01L 27/02; H01L 21/8238; H01L 29/161; H01L 29/06; H01L 21/28; H01L 21/762; H01L 29/10; H01L 29/423; H01L 27/092; H01L 29/788

(52) U.S. Cl. CPC H01L 27/0207; H01L 27/092; H01L 21/823878; H01L 29/161; H01L 29/788; H01L 21/823807; H01L 21/28273; H01L 21/76224; H01L 29/1033; H01L 29/42324; H01L 29/0649

(57) ABSTRACT

The present disclosure provides an integrated circuit product including a plurality of standard cells, each standard cell of the plurality of standard cells being in abutment with at least one other standard cell of the plurality of standard cells, a continuous active region continuously extending across the plurality of standard cells, at least two active regions being separated by an intermediate diffusion break, wherein each standard cell comprises at least one PMOS device and at least one NMOS device, the at least one PMOS device being provided in and above the continuous active region and the at least one NMOS device being provided in and above the at least two active regions.

### BACKGROUND

### 1. Field of the Disclosure

The present disclosure relates to a standard cell layout and to a method of arranging a plurality of standard cells, and, more particularly, to designing a standard cell layout having a continuous active region which continuously extends across a plurality of standard cells, and at least two active regions that are separated by an intermediate diffusion break.

### 2. Description of the Related Art

Conventional standard cell libraries in semiconductor integrated circuits (ICs) primarily contain a logic cell layout based on a metal oxide semiconductor (MOS) environment, particularly a complementary metal oxide semiconductor (CMOS) environment. Generally, a standard cell library represents a collection of standard cells, wherein a standard cell is a predesigned layout of transistors or non-specific collection of logic gates that are typically designed with the help of computer assisted design (CAD) applications. The standard cells are usually interconnected or wired together in a particular manner by means of a placement and routing tool to perform a specific type of logic operation in an application specific IC (ASIC).

Conventional ASIC layouts are typically defined by an array of logic cells arranged in several adjacent rows. The components of the logic cells, such as PMOS and NMOS transistor devices, are wired by means of vias and metal layers in order to form simple logic (NMOS and PMOS) gates performing Boolean and logic functions, such as INVERTER, AND, OR, NAND, NOR, XOR, XNOR, and the like. In the design of the interconnection layout, integrated circuit design rules must be observed, such as, for example, minimum width of transistor width, minimum width of metal tracks, and the like.

In a design process for designing integrated circuits, standard cells of the standard cell library are retrieved from the standard cell library and placed into desired locations, followed by a step of routing to connect the placed standard cells with each other and with other circuits on a semiconductor chip. When placing the standard cells into desired locations on the semiconductor chip, predefined design rules are to be followed, that is, rules defining spacing of active regions apart from cell boundaries, such that, upon placing standard cells in an abutting arrangement, active regions of neighboring cells are properly placed without incurring area penalties. Herein, the reserved space between active regions of neighboring standard cells and the reserved space between the active regions and the cell boundaries results in a significant increase in the areas of the standard cells. In the case of active regions being spaced apart from cell boundaries, the active regions will not be joined when placing standard cells in abutment with each other, leading to an issue regarding stress occurring in materials near an interface of different materials with different crystallographic structures or thermal expansion coefficients. For example, within a cell, stress occurring in the material of an active region close to an interface to a surrounding insulating material, such as shallow trench isolation (STI) regions, strain may be created within the cell, the strain impacting the performance of NMOS and PMOS devices within the standard cell, causing undesired variations in their output performance. A conventional standard cell may include non-active regions, for example, STI regions, which surround active regions within the standard cell. In case that a standard cell has more than two stages, the non-active regions usually act to isolate active regions from one another and to form cell boundaries between standard cells at the block level. The active regions generally represent discreet islands of semiconducting substrate materials on which semiconductor devices are to be formed, these discreet islands being defined in the semiconductor substrate by the STI regions.

It is desirable to provide a standard cell layout and a method of arranging a plurality of standard cells such that degradation of transistor performance close to diffusion edges (i.e., interfaces between active and non-active regions) is reduced, if not avoided.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In a first aspect of the present disclosure, a standard cell layout is provided. In accordance with some illustrative embodiments herein, the standard cell layout includes a plurality of standard cells, each standard cell of the plurality of standard cells being in abutment with at least one other standard cell of the plurality of standard cells, a continuous active region continuously extending across the plurality of standard cells, at least two active regions being separated by an intermediate diffusion break, wherein each standard cell comprises at least one PMOS device and at least one NMOS device, the at least one PMOS device being provided in and above the continuous active region and the at least one NMOS device being provided in and above the at least two active regions.

In a second aspect of the present disclosure, a method of arranging a plurality of standard cells is provided. In accordance with some illustrative embodiments herein, the method of arranging a plurality of standard cells includes placing at least two standard cells in an abutting arrangement, each of the at least two standard cells having at least two active regions, wherein each standard cell of the at least two standard cells has at least one PMOS device and at least one NMOS device, wherein, upon placing the at least two standard cells in the abutting arrangement, a continuous active region continuously extending across the at least two standard cells is formed, wherein the at least two abutting standard cells comprise at least two active regions being separated by an intermediate diffusion break, and wherein the at least one PMOS device is provided in and above the continuous active region and the at least one NMOS device is provided in and above the at least two active regions.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a schematic top view of a standard cell layout in accordance with some illustrative embodiments of the present disclosure;

FIG. 2 schematically illustrates a schematic top view of the standard cell layout of FIG. 1 at a more advanced level;

FIG. 3 schematically illustrates a schematic top view of the standard cell layout of FIGS. 1 and 2 at a still more advanced level; and

FIG. 4 schematically illustrates a schematic top view of the standard cell layout of FIG. 1-3 at a still more advanced level.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

In various aspects, the present disclosure relates to a method of forming a capacitor structure and to a capacitor structure, wherein the capacitor structures are integrated on or in a chip. In accordance with some illustrative embodiments of the present disclosure, the capacitor structure may substantially represent a metal-insulator-metal (MIM) structure. When referring to MIM structures, the person skilled in the art will appreciate that, although the expression “MIM structure” is used, no limitation to metal-containing electrode materials is intended.

Semiconductor devices, such as PMOS and NMOS devices, of the present disclosure may concern structures which are fabricated by using advanced technologies, i.e., the semiconductor devices may be fabricated by technologies applied to approach technology nodes smaller than 100 nm, for example, smaller than 50 nm or smaller than 35 nm, e.g., at 22 nm or below. The person skilled in the art will appreciate that, according to the present disclosure, ground rules smaller than or equal to 45 nm, e.g., at 22 nm or below, may be imposed. The person skilled in the art will appreciate that the present disclosure proposes capacitor structures having minimal length dimensions and/or width dimensions smaller than 100 nm, for example, smaller than 50 nm or smaller than 35 nm or smaller than 22 nm. For example, the present disclosure may provide structures fabricated by using 45 nm technologies or below, e.g., 22 nm or even below. However, the statements herein regarding possible technology nodes should not be considered to constitute a limitation of the presently disclosed subject matter.

In accordance with some illustrative embodiments, the semiconductor devices may be implemented in and above a substrate, such as a bulk substrate (e.g., a semiconductor bulk material as known in the art) or an FDSOI substrate. For example, FDSOI substrates may have a thin (active) semiconductor layer disposed on a buried insulating material layer, which, in turn, may be formed on a substrate material. In accordance with some illustrative embodiments herein, the semiconductor layer may comprise one of silicon, silicon germanium and the like. The buried insulating material layer may comprise an insulating material, e.g., silicon oxide or silicon nitride. The semiconductor substrate material may be a base material that is used as a substrate in the art, e.g., silicon, silicon germanium and the like. The person skilled in the art will appreciate that, in accordance with FDSOI substrates, the semiconductor layer may have a thickness of 20 nm or less, while the buried insulating material layer may have a thickness of about 145 nm or, in accordance with advanced techniques, the buried insulating material layer may have a thickness in a range from 10-30 nm. For example, in some illustrative embodiments of the present disclosure, the semiconductor layer may have a thickness of 6-10 nm.

Although a semiconductor device may be provided by a MOS device, the expression “MOS” does not imply any limitation to the subject matter disclosed herein, i.e., a MOS device is not limited to a metal-oxide-semiconductor configuration, but may also comprise a semiconductor-oxide-semiconductor configuration and the like.

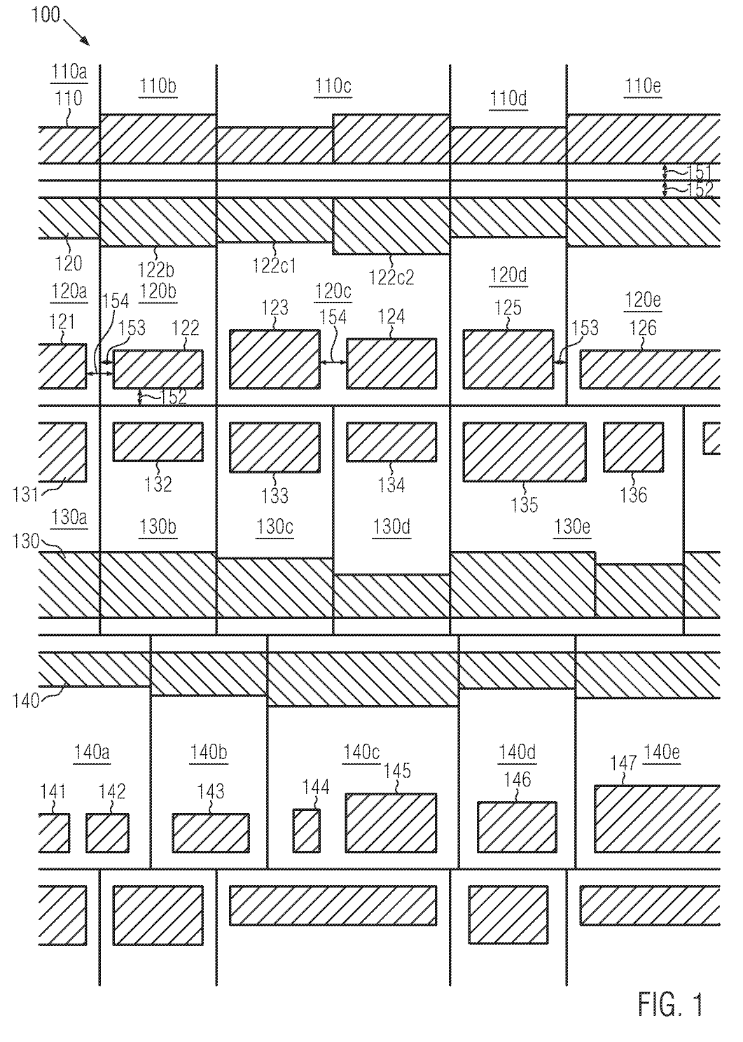

FIG. 1 schematically illustrates a standard cell layout 100 comprising a plurality of standard cells 110a, 110b, 110c, 110d, 110e, 120a, 120b, 120c, 120d, 120e, 130a, 130b, 130c, 130d, 130e, 140a, 140b, 140c, 140d and 140e. The standard cells of the plurality of standard cells may be arranged in an abutting arrangement, wherein each standard cell of the plurality of standard cells may abut at least one other standard cell of the plurality of standard cells. For example, the standard cells of the plurality of standard cells may be arranged in abutting rows, the standard cells within each row being in abutment with at least one other standard cell of the standard cells of this row.

Referring to FIG. 1, the standard cells 110a, 110b, 110c, 110d and 110e may be arranged such that the standard cell 110a may abut the standard cell 110b, which in turn may abut the standard cell 110c, which in turn may abut the standard cell 110d, which in turn may abut the standard cell 110e.

Similarly, the standard cells 120a, 120b, 120c, 120d and 120e may be arranged in a row of standard cells, wherein the standard cell 120a may abut the standard cell 120b, which in turn may abut the standard cell 120c, which in turn may abut the standard cell 120d, which in turn may abut the standard cell 120e.

Similarly, the standard cells 130a, 130b, 130c, 130d and 130e may be arranged in a row, wherein the standard cell 130a may abut the standard cell 130b, which in turn may abut the standard cell 130c, which in turn may abut the standard cell 130d, which in turn may abut the standard cell 130e.

Similarly, the standard cells 140a, 140b, 140c, 140d and 140e may be provided in a row of standard cells, wherein the standard cell 140a may abut the standard cell 140b, which in turn may abut the standard cell 140c, which in turn may abut the standard cell 140d, which in turn may abut the standard cell 140e.

Referring to FIG. 1, at least some of the standard cells of the various rows may be arranged to form a column of standard cells, such as the standard cells 110a, 120a and 130a being arranged in a column, for example.

In accordance with some special illustrative embodiments of the present disclosure, each of the standard cells within a row may have equal width dimensions, that is, a dimension that is measured along a vertical direction in FIG. 1 may be the same for all standard cells within each row. By contrast, a horizontal direction in FIG. 1 may denote a direction perpendicular to a direction along which the plural standard cells of each row are arranged.

In accordance with some illustrative embodiments of the present disclosure, the various standard cells 110a to 140e may represent suitable standard cells that are selected from a predefined library of standard cells. Although these standard cells may be illustrated in FIG. 1 in a very schematic way, particularly a way in which details of standard cell layout are omitted for the sake of clarity, the person skilled in the art will appreciate that this is only for illustrative purposes. After a complete reading of the present disclosure, the person skilled in the art will appreciate that the standard cells 110a to 140e may be implemented using any conventional integrated circuit layout that is configured to provide Boolean logic functions, such as AND, OR, XOR, XNOR, or NOT, to provide some examples, or storage functions, such as a flipflop or a latch to provide some examples.

In accordance with some illustrative embodiments as depicted in FIG. 1, each of the standard cells 110a to 140e may comprise at least two active diffusion regions formed within one or more diffusion layers. In accordance with some special illustrative embodiments of the present disclosure, the active diffusion regions may represent active diffusion regions provided within a semiconductor substrate, such as an FDSOI substrate in the case of FDSOI applications, or a bulk substrate in the case of bulk applications, upon which active diffusion regions, one or more semiconductor devices, e.g., PMOS and/or NMOS devices, may be formed. In accordance with some illustrative embodiments of the present disclosure, at least one active diffusion region of the plurality of active diffusion regions formed within each standard cell may be doped with impurity atoms of an acceptor type, such as boron or aluminum, to form active regions of P-type metal oxide semiconductor (PMOS) devices. Alternatively or additionally, at least one of the active diffusion regions may be doped with impurity atoms of a donor type, such as phosphorus, arsenic or antimony, to form active regions of N-type metal oxide semiconductor (NMOS) devices.

In accordance with some illustrative embodiments of the present disclosure, a standard cell may have at least two active diffusion regions. For each type of semiconductor device, at least one active diffusion region may be provided. Each standard cell may be configured for accommodating at least one PMOS device and at least one NMOS device.

With regard to FIG. 1, as it is schematically illustrated with regard to the standard cell 120b, the standard cell 120b comprises two active diffusion regions 122b and 122. The active diffusion region 122b may be formed within the standard cell 120b such that a design rule, such as indicated by a spacing 152 to an upper horizontal boundary or outline of the standard cell 120b, is complied with. However, regarding vertical boundaries of the standard cell 120b, the active diffusion region 122b may substantially extend from one vertical boundary to the opposite vertical boundary of the standard cell 120b, i.e., the active diffusion region 122b completely extends across the standard cell 120b in the horizontal direction.

Regarding the active diffusion region 122 of the standard cell 120b as depicted in FIG. 1, the active diffusion region 122 is disposed within the standard cell 120b in accordance with design rules defining the spacing 152 to a lower boundary of the standard cell 120b, as well as defining a spacing 153 to the vertical boundaries of the standard cell 120b. That is, the active diffusion region 122 may be completely placed within the standard cell 120b and, particularly, the active diffusion region 122 may not be in contact with any boundary of the standard cell 120b. In the following, active diffusion regions not having contact with boundaries of standard cells, such as the active diffusion region 122 of the standard cell 120b, will be in the following referred to as “active region.” By contrast, an active diffusion region being in contact with opposing boundaries of a standard cell, such as the active diffusion region 122b, these active diffusion regions will be in the following referred to as “continuous active region.” Continuous active regions of two or more abutting standard cells thus form a continuous active region extending across the two or more abutting standard cells.

With regard to FIG. 1, the standard cell 120c has two active regions 123 and 124, which are spaced apart from each other in accordance with design rules, such as a spacing 154. Furthermore, the standard cell 120c has a continuous active region being formed by two abutting active diffusion regions 122c1 and 122c2 which completely extend across the standard cell 120c from one vertical boundary to an opposing vertical boundary of the standard cell 120c. In accordance with some illustrative embodiments of the present disclosure, each of the diffusion regions of a standard cell, such as the diffusion regions 122b and 122 within the standard cell 120b, or the diffusion regions 122c1, 122c2, 123 and 124 may have equal or different width dimensions (i.e., dimensions measured along the vertical direction in FIG. 1). FIG. 1 schematically illustrates exemplary embodiments in which active diffusion regions within a standard cell may have different width dimensions.

In accordance with the illustration of FIG. 1, the standard cell layout 100 may comprise a plurality of standard cells that are in an abutting arrangement, particularly the standard cells within each row of standard cells are in an abutting arrangement, such as the standard cells 110a, 110b, 110c, 110d and 110e, or the standard cells 120a, 120b, 120c, 120d and 120e, or the standard cells 130a, 130b, 130c, 130d and 130e, or 140a, 140b, 140c, 140d and 140e. Herein, the standard cells 120a and 120b may be in abutment with each other such that the continuous active regions within each of the standard cells 120a and 120b are in abutment, providing a continuous active region extending across both abutting active regions 120a and 120b. The abutting standard cells 120a and 120b may further comprise the two active regions 121 and 122 which are separated by an intermediate diffusion break as indicated by reference numeral 154 in FIG. 1. Similarly, the standard cell 120b may be in abutment with the standard cell 120c, such that the diffusion regions 122b, 122c1 and 122c2 may abut for forming a continuous active region extending across the standard cells 120b and 120c. Similarly, the active regions 122, 123 and 124 are separated by intermediate diffusion breaks, such as the spacing 154.

Referring to FIG. 1, the standard cells 110a, 110b, 110c, 110d and 110e may comprise a continuous active region 110. Similarly, the standard cells 120a, 120b, 120c, 120d and 120e may comprise a continuous active region 120. Similarly, the standard cells 130a, 130b, 130c, 130d and 130e may comprise an active region 130. Similarly, the standard cells 140a, 140b, 140c, 140d and 140e may comprise an active region 140. Upon considering each of the standard cells within a row as providing a plurality of standard cells which are in an abutting arrangement, each plurality of standard cells in an abutting arrangement may comprise a continuous active region, e.g., the continuous active regions 110, 120, 130 and 140, and at least one active region, e.g., the active regions 121, 122, 123, 124, 125 and 126 in case of the standard cells 120a, 120b, 120c, 120d and 120e, or the active regions 131, 132, 133, 134, 135 and 136 in case of the standard cells 130a, 130b, 130c, 130d and 130e, or the active regions 141, 142, 143, 144, 145, 146 and 147 in case of the standard cells 140a, 140b, 140c, 140d and 140e.

In accordance with some illustrative embodiments comprising the standard cells 110a to 110e, the continuous active region 110 may continuously extend across the standard cells 110a to 110e. In case of the standard cells 120a to 120e, the continuous active region 120 may continuously extend across the standard cells 120a to 120e. In case of the standard cells 130a to 130e, the continuous active region 130 may continuously extend across the standard cells 130a to 130e. In case of the standard cells 140a to 140e, the continuous active region 140 may continuously extend across the standard cells 140a to 140e.

In accordance with some illustrative embodiments of the present disclosure, at least one of the continuous active regions 110 to 140 may be doped with impurity atoms of an acceptor type, such as boron or aluminum.

In accordance with some illustrative embodiments, at least one of the active regions 121 to 147 may be doped with impurity atoms of a donor type, such as phosphorous, arsenic or antimony.

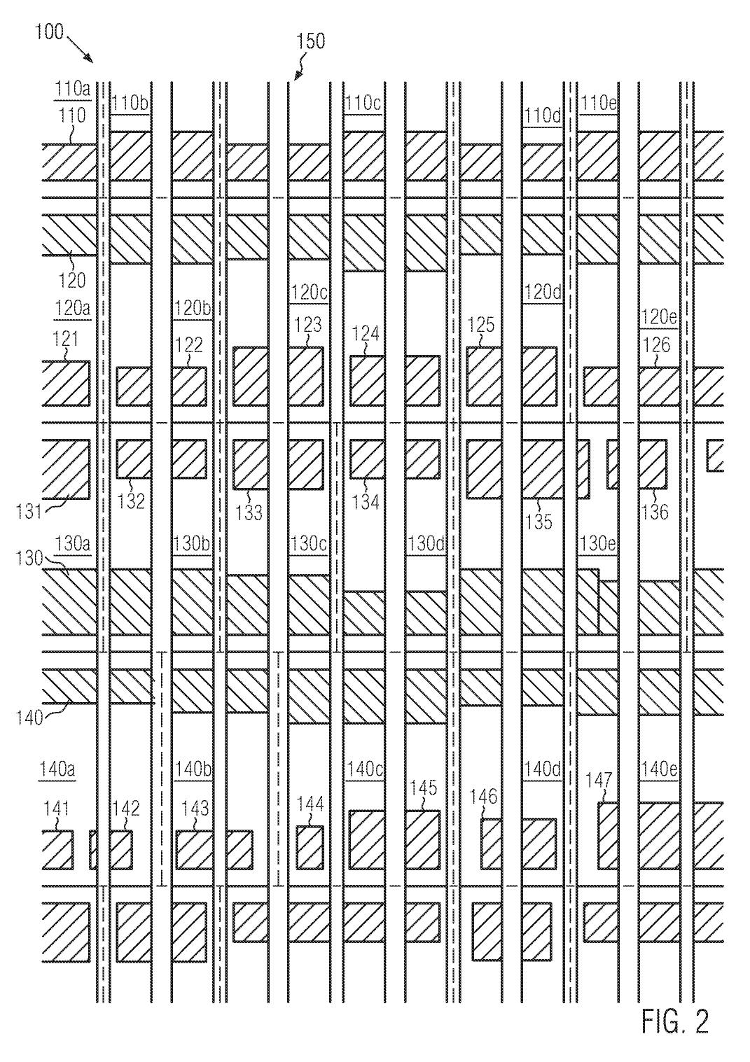

Referring to FIG. 2, a standard cell layout in accordance with some illustrative embodiments of the present disclosure is schematically illustrated. The standard cell layout 100 as schematically illustrated in FIG. 2 may substantially correspond to the arrangement of standard cells as described above with regard to FIG. 1, however, at a more advanced level of complexity. For example, FIG. 2 may differ from FIG. 1 in that the standard cell layout 100 of FIG. 2 is less schematic and shows a plurality of gate lines 150. Each of the gate lines of the plurality of gate lines 150 may basically extend across each of the continuous active regions 110, 120, 130 and 140. In accordance with some illustrative embodiments of the present disclosure, the plurality of gate lines 150 may comprise equally spaced or equidistantly placed gate lines. However, this does not pose any limitation to the present disclosure and the person skilled in the art will appreciate that the gate lines may not be equally spaced.

In accordance with some illustrative embodiments of the present disclosure, some of the gate lines of the plurality of gate lines 150 may be substantially disposed over boundaries of at least some of the standard cells, as it is indicated by a broken line in FIG. 2 within some of the gate lines. However, this does not pose any limitation to the present disclosure and the person skilled in the art will appreciate that, alternatively, none of the gate lines may be disposed over a boundary of the standard cells.

In accordance with some illustrative embodiments of the present disclosure, each of the gate lines of the plurality of gate lines 150 may be formed by one or more polysilicon and/or gate metal layers. Each of the gate lines of the plurality of gate lines 150 may further comprise a gate oxide for electrically insulating the polysilicon layer and/or gate metal layer from the underlying active region and/or continuous active region. The person skilled in the art will appreciate that details of the gate lines, as described above, are omitted in the figures.

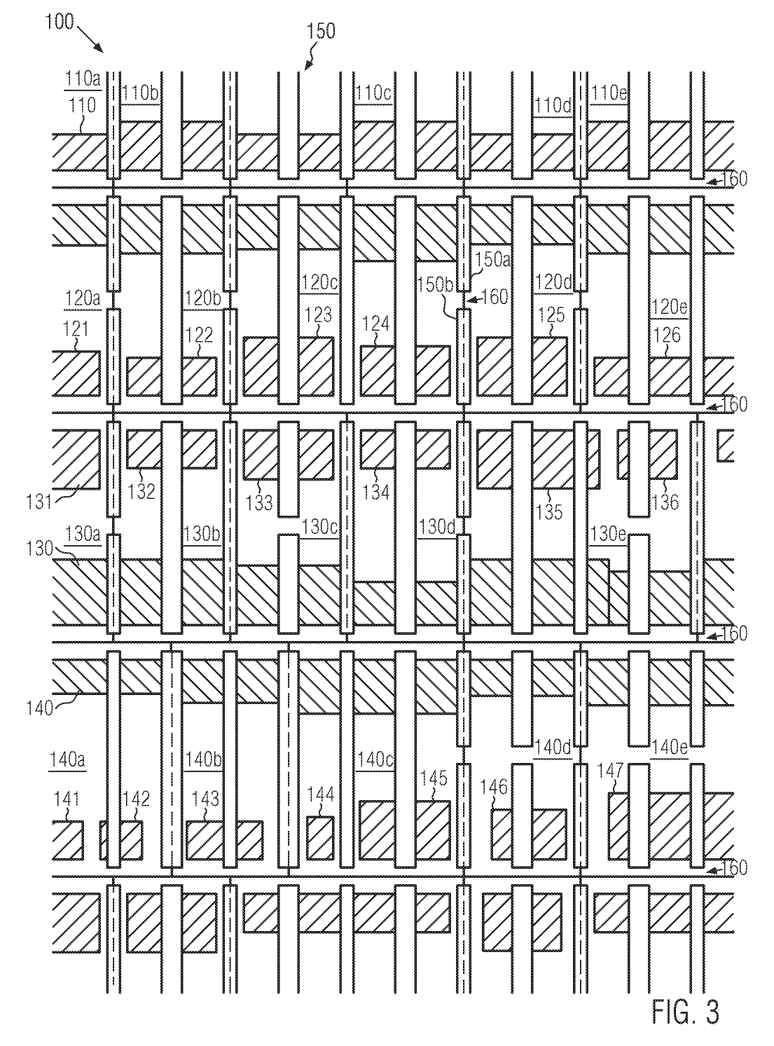

Referring to FIG. 3, the standard cell layout 100 of FIG. 2 is schematically illustrated after the gate lines of the plurality of gate lines 150 are split by one or more cuts, as indicated by reference numeral 160 in FIG. 3. Accordingly, the gate lines extending across several rows of standard cells may be interrupted by according cuts 160 such that each gate line of the plurality of gate lines 150 completely lies within one row of standard cells. Optionally, gate lines lying within a row of standard cells may be further interrupted by a cut 160, such as the gate lines 150a and 150b being disposed over an interface between the two neighboring standard cells 120c and 120d.

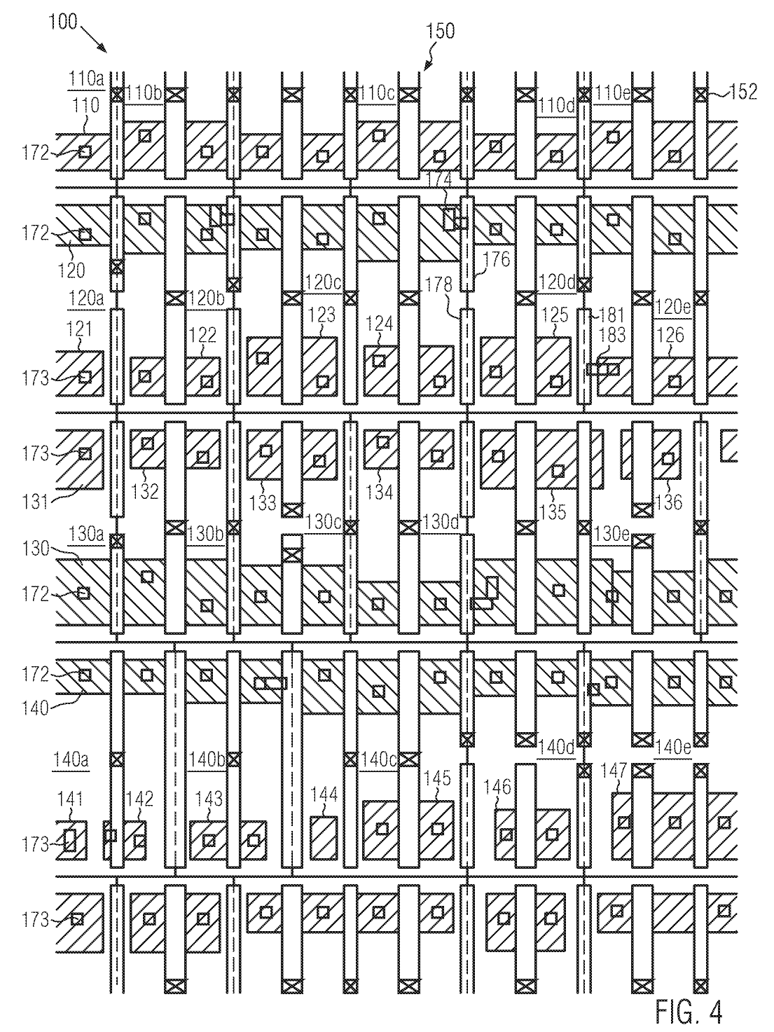

Referring to FIG. 4, the standard cell layout 100 of FIG. 3 is schematically illustrated at a more advanced level of complexity, that is, at the level of contact 172 contacting the continuous active regions 110 to 140, contacts 173 to the active regions 121 to 147, and contacts 152 to the gate lines of the plurality of gate lines 150.

In accordance with some illustrative embodiments of the present disclosure, the standard cell layout 100 as depicted in FIG. 4 may comprise at least one floating gate, such as a floating gate 176 which is provided over the continuous active region 120. The floating gate 176 may be provided over the continuous active region 120 between two adjacent PMOS devices. For example, the floating gate 176 may be disposed over a vertical boundary of the standard cell 120c and the standard cell 120d. In accordance with some special illustrative examples, the floating gate 176 may be electrically coupled to the continuous active region 120 by means of a contact structure 174. The contact structure 174 may comprise a metal line portion coupled to a via contact, the vertical line portion substantially extending parallel to an upper surface of the continuous active region 120, while the via contact being perpendicular to the upper surface of the continuous active region 120. Accordingly, the floating gate 176 may be electrically connected to one of a source contact and a drain contact of an adjacent PMOS device.

In accordance with some illustrative embodiments of the present disclosure, gate lines that substantially extend across an intermediate diffusion break, such as a gate line 178 extending across an intermediate diffusion break between the active regions 124 and 125, may not be contacted.

In accordance with some illustrative embodiments of the present disclosure, a floating gate 181 may be provided over the active region 126, wherein the floating gate 181 may extend along an interface between the active region 126 and an intermediate diffusion break between the active region 126 and the active region 125. The floating gate 181 may be electrically connected to the active region 126 by means of a contact structure 183, the contact structure 183 being substantially similar to the contact structure 174, e.g., comprising a metal line and a via contact.

In accordance with some illustrative embodiments of the present disclosure, at least one of the standard cells 110a to 140e may implement an inverter. Additionally or alternatively, the standard cells may implement at least one of AND, OR, XOR, XNOR, and NOT, to provide some examples, or a storage function, such as a flipflop or a latch, to provide some examples.

In accordance with some illustrative embodiments of the present disclosure, intermediate diffusion breaks may be formed by an insulating structure, such as a shallow trench isolation (STI) structure. The person skilled in the art will appreciate that active regions may be defined and/or delineated by surrounding STIs.

In accordance with some illustrative embodiments of the present disclosure, at least one of the continuous active regions 110 to 140 may comprise silicon germanium.

In accordance with some illustrative embodiments of the present disclosure, the continuous active regions 110 to 140 may be separated from the active regions 121 to 147 by means of at least one STI. In accordance with some illustrative embodiments of the present disclosure, two adjacent continuous active regions may be separated by at least one STI.

In accordance with some special illustrative and not limiting examples of the present disclosure, the continuous active regions 110 to 140 may have a length dimension extending in a vertical direction in the figures of more than about 50 nm, e.g., of more than about 100 nm.

With regard to FIGS. 2-4, schematic top views of standard cell layouts in accordance with some illustrative embodiments of the present disclosure are provided. The person skilled in the art will appreciate that the schematic top views do not indicate any cut of the shape of any active region by any gate structure.

The person skilled in the art will appreciate that, in case that active source and/or drain regions of neighboring transistors are on different potentials, sufficient isolation is necessary between the active source/drain regions at different potentials. In accordance with some illustrative examples, isolation between such active source/drain regions of neighboring transistors may be provided by means of an isolation structure, e.g., a shallow trench isolation (STI) structure or another isolating structure, e.g., an oxide structure isolating neighboring active source/drain regions at different potentials.

In accordance with some illustrative embodiments of the present disclosure, a continuous active region design may be proposed, wherein the continuous active region design comprises an isolation which may be accomplished by a tie gate, that is, a gate which is connected to a source potential (VDD or VSS) between the two neighboring regions at different potential, the neighboring regions forming an active cut mask or the need to unnecessarily pattern a small active space. In accordance with some special examples, the tight gates may represent floating gates which are connected to one of a source potential and a drain potential of a neighboring source/drain region.

In accordance with some illustrative embodiments of the present disclosure, a loss of transistor performance due to a proximity of PMOS devices close to diffusion edges in standard cell design may be circumvented by providing a continuous active region design for PMOS devices in abutting standard cell arrangements, where the continuous active region extends across at least two abutting standard cells. For example, degradation in the performance of PMOS devices caused by close proximity to intermediate diffusion breaks may at least be reduced. Furthermore, a reduced usage of yield delimiting special constructs for tight gate isolation and drain/drain neighborhood situations is present. Furthermore, leakage caused by tight gate isolating and drain/drain neighborhood situations may be reduced and the necessity of placement fillers between cell boundaries in drain/drain situations may be reduced. Furthermore, additional inter-cell routing resources may be provided by using less tight gate constructs. Due to the continuous active region in the standard cell layout for PMOS devices, inter-cell placement constraints are only needed for PMOS sub-edges of standard cell boundaries.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. An integrated circuit product, comprising:
a plurality of standard cells, each standard cell of said plurality of standard cells being in abutment with at least one other standard cell of said plurality of standard cells;
a continuous active region continuously extending across said plurality of standard cells; and
at least two active regions being separated by an intermediate diffusion break, wherein each standard cell comprises at least one PMOS device and at least one NMOS device, said at least one PMOS device being provided in and above said continuous active region and said at least one NMOS device being provided in and above said at least two active regions.

2. The product of claim 1, wherein said continuous active region comprises silicon germanium.

3. The product of claim 1, wherein said intermediate diffusion break is a trench isolation.

4. The product of claim 1, wherein said continuous active region is separated from said at least two active regions by a trench isolation.

5. The product of claim 1, wherein at least one standard cell of said plurality of standard cells implements an inverter.

6. The product of claim 1, wherein said continuous active region has a length of at least about 50 nm.

7. The product of claim 1, further comprising a floating gate provided over said continuous active region between adjacent PMOS devices.

8. The product of claim 7, wherein said floating gate extends along an interface between two neighboring standard cells.

9. The product of claim 7, wherein said floating gate is electrically connected to one of a source contact and a drain contact of an adjacent PMOS device.

10. The product of claim 1, further comprising a floating gate provided over one of said two active regions, said floating gate extending along an interface between said one of said two active regions and said diffusion break.

11. A method of making an integrated circuit product, comprising:
placing at least two standard cells in an abutting arrangement, each of said at least two standard cells having at least two active regions, wherein each standard cell of said at least two standard cells has at least one PMOS device and at least one NMOS device;
forming a continuous active region continuously extending across said at least two standard cells; and
forming at least two active regions that are separated by an intermediate diffusion break in said at least two abutting standard cells, wherein said at least one PMOS device is provided in and above said continuous active region and said at least one NMOS device is provided in and above said at least two active regions.

12. The method of claim 11, wherein said continuous active region comprises silicon germanium.

13. The method of claim 11, wherein said intermediate diffusion break comprises a shallow trench isolation.

14. The method of claim 11, further comprising forming a shallow trench isolation that separates said continuous active region from said at least two active regions.

15. The method of claim 11, wherein at least one standard cell of said at least two standard cells implements an inverter.

16. The method of claim 11, further comprising forming a floating gate over said continuous active region between adjacent PMOS devices.

17. The method of claim 16, wherein said floating gate extends along an interface between two neighboring standard cells.

18. The method of claim 16, wherein forming said floating gate comprises forming a poly gate line which extends across said continuous active region and one of said at least two active regions, replacing a portion of said poly gate line with a floating gate material stack, said portion extending across said continuous active region, and separating said portion from said remaining poly gate line forming said floating gate, wherein a poly gate extending across said one of said at least two active regions is formed.

19. The method of claim 11, further comprising forming a floating gate over one of said two active regions, said floating gate extending along an interface between said one of said two active regions and said diffusion break.

20. The method of claim 19, wherein forming said floating gate comprises forming a poly gate line which extends across said continuous active region and along an interface between said one of said two active regions and said diffusion break, replacing a portion of said poly gate line over said one of said at least two active regions by a floating gate material stack, and separating said portion from said remaining poly gate line via a cut forming said floating gate, wherein a poly gate extending across said continuous active region is formed.
